(19) United States
(12) Patent Application Publication
(10) Pub. No.: US 2012/0085399 A1
(43) Pub. Date: Apr. 12, 2012

(54) REO-Ge Multi-Junction Solar Cell

(75) Inventors: Michael S. Lebby, Palo Alto, CA (US); Andrew Clark, Palo Alto, CA (US); Robin Smith, Palo Alto, CA (US)

(73) Assignee: TRANSLUCENT, INC., Palo Alto, CA (US)

(21) Appl. No.: 13/336,664

(22) Filed: Dec. 23, 2011

Related U.S. Application Data
(63) Continuation of application No. 13/020,766, filed on Feb. 3, 2011.
Application No. 13/020,766 is a continuation-in-part of application No. 12/408,297, filed on Mar. 20, 2009, now Pat. No. 8,039,736.
Application No. 12/408,297 is a continuation-in-part of application No. 12/510,977, filed on Jul. 28, 2009.
Application No. 12/510,977 is a continuation-in-part of application No. 12/619,637, filed on Nov. 16, 2009, now Pat. No. 8,039,738.
Application No. 12/619,637 is a continuation-in-part of application No. 12/619,621, filed on Nov. 16, 2009, now Pat. No. 8,049,100.
Application No. 12/619,621 is a continuation-in-part of application No. 12/619,549, filed on Nov. 16, 2009, now Pat. No. 8,039,737.
(60) Provisional application No. 61/301,597, filed on Feb. 4, 2010.

(51) Int. Cl. H01L 31/0352

(52) U.S. Cl. 136/255

(57) ABSTRACT

The invention relates to a semiconductor based structure for a device for converting radiation to electrical energy comprising various combinations of rare-earths and Group IV, III-V, and II-VI semiconductors and alloys thereof enabling enhanced performance including high radiation conversion efficiency.

### PRIORITY

This application is a continuation of and claims priority from U.S. Ser. No. 13/020,766. U.S. Ser. No. 13/020,766 claims priority from U.S. Provisional Application 61/301,597 filed on Feb. 4, 2010 and is a continuation-in-part of Ser. No. 12/408,297, filed on Mar. 20, 2009, Ser. No. 12/510,977, filed on Jul. 28, 2009, and Ser. Nos. 12/619,637, 12/619,621, 12/619,549, all filed on Nov. 16, 2009 and claims priority from these applications, all included herein in their entirety by reference.

### CROSS REFERENCE TO RELATED APPLICATIONS

Applications and patents, U.S.20050166834, Ser. Nos. 11/257,517, 11/257,597, 11/393,629, 11/472,087, 11/559,690, 11/599,691, 11/828,964, 11/858,838, 11/873,387 11/960,418, 11/961,938, 12/119,387, 60/820,438, 61/089,786, Ser. Nos. 12/029,443, 12/046,139, 12/111,568, 12/119,387, 12/171,200, 12/510,977, 12/632,741, 12/651,419, 12/890,537, 12/932,979, 13/015,315, 13/251,086, 61/298,896, 61/312,061, U.S. Pat. No. 6,734,453,U.S. Pat. No. 6,858,864, U.S. U.S. Pat. No. 7,018,484,U.S. Pat. No. 7,023,011 U.S. Pat. No. 7,037,806,U.S. Pat. No. 7,135,699,U.S. Pat. No. 7,199,015,U.S. Pat. No. 7,211,821, U.S. U.S. Pat. No. 7,217,636,U.S. Pat. No. 7,273,657,U.S. Pat. No. 7,253,080,U.S. Pat. No. 7,323,737,U.S. Pat. No. 7,351,993,U.S. Pat. No. 7,355,269, U.S. U.S. Pat. No. 7,364,974, U.S. Pat. No. 7,384,481,U.S. Pat. No. 7,416,959, U.S. Pat. No. 7,432,569, U.S. Pat. No. 7,476,600,U.S. Pat. No. 7,498,229, U.S. Pat. No. 7,586,177, U.S. U.S. Pat. No. 7,599,623, U.S. U.S. Pat. No. 7,655,327, U.S. U.S. Pat. No. 7,645,517, U.S. U.S. Pat. No. 7,902,546, U.S. U.S. Pat. No. 7,928,317, U.S. U.S. Pat. No. 8,039,736, U.S. U.S. Pat. No. 8,039,737, U.S. U.S. Pat. No. 8,039,738, U.S. U.S. Pat. No. 8,049,100, U.S. U.S. Pat. No. 8,071,872, all held by the same assignee, contain information relevant to the instant invention and are incorporated herein in their entirety by reference. References, noted in the specification and Information Disclosure Statement, are included herein in their entirety by reference.

### BACKGROUND OF THE INVENTION

1. Field of the Invention

The invention relates to a semiconductor based structure for a device for converting radiation to electrical energy comprising various combinations of rare-earths and Group IV, III-V, and II-VI semiconductors and alloys thereof enabling enhanced performance including high radiation conversion efficiency.

2. Description of Related Art

Prior art is found in U.S. U.S. Pat. No. 5,548,128, U.S. U.S. Pat. No. 4,834,501, U.S. U.S. Pat. Nos. 7,598,513, 7,589,003 2007/0020891, U.S. 2008/0277647 and U.S. 2008/0187768; all included herein in their entirety by reference. Additional art is found in App. Phy. Lett., 86, 191912 (2005); App. Phy. Letters, 88, 252112, 2006; App. Phy. Letters, 89, 231924, 2006; Kouvetakis, John “Independently tunable electronic and structural parameters in ternary Group IV semiconductors for optoelectronic applications”; all included herein in their entirety by reference.

Crystalline Si has enjoyed spectacular success in the solar cell industry for various reasons including the ability to benefit from technological breakthroughs in the microelectronics industry and the close proximity of the 1.1 eV band gap value of Si to the optimal theoretical 1.3 eV band gap value for which the thermodynamically limited single-cell efficiency reaches a maximum value. Since modern single-cell crystal solar technology appears to be approaching the maximum expected efficiency, efforts to increase the competitiveness of these cells have focused on decreasing the cell thickness and thereby reducing silicon consumption. Still, ultra-thin Si cells face a fundamental limitation. The lowest energy direct optical transition in this material occurs at 3.5 eV, and therefore, its absorption below this threshold is very low because only phonon-assisted transitions are possible. On the other hand, thinner films have certain advantages because the ratio of carrier diffusion length to thickness is larger, thereby increasing the collection efficiency of minority carriers. The ideal compromise for maximum efficiency is estimated to be approximately 150 μm. Consequently, the industry is also approaching a fundamental limit when it comes to savings by reducing the Si thickness.

Researchers at Arizona State University have developed a method to fabricate Si/GeSn and/or Si/Ge tandem cells that take advantage of chemical vapor deposition (CVD) techniques allowing growth of Ge and GeSn on silicon substrates. The resulting potential efficiencies substantially exceed that of traditional Si solar cells and represent the most promising approach to advance Si-cell technology. Increased Efficiency—traditional Si cells offer maximum thermodynamic efficiency of ≈35% (requires thick Si) compared to ≈40% efficiency offered by new method for ultra-thin Si; traditional Si operates at ≈21% for actual commercial values and down to ≈15% at a 25 μm thickness. Allows Dramatic Reductions in Material Thickness—GeSn/Ge thicknesses below 10 μm and even below 1 μm for certain applications sufficient for 90% light absorption compared to the optimal 150 μm value needed for traditional Si solar cells. Eliminates Need for Light Trapping Features—traditional methods require special texturing or rear surface reflectors; significance of advantage increases as thickness decreases.

Doped and intrinsic Ge_{1-x-y}SiₓSn_{y} alloys are synthesized directly on Si(100) using simple deposition chemistries and their optical and electrical properties are determined. Tuning the Si/Sn ratio at ˜4 yields strain-free films with Ge-like cell dimensions, while variation of the ratio around this value produces compressively strained, tetragonal structures with an in-plane lattice constant “pinned” to a value close to that of pure Ge (5.658 Å). First-principles calculations show that mixing entropy thermodynamically stabilizes SiGeSn in contrast to GeSn analogs with the same Sn content. GeSn and SiGeSn are predicted to become metastable for 2% and 12% Sn, respectively, in good agreement with experiment.

The optical properties of Ge_{1-y}Sn_{y} alloys (y˜0.02) grown by chemical vapor deposition on Si substrates have been studied using spectroscopic ellipsometry and photocurrent spectroscopy. The system shows a 10-fold increase in optical absorption, relative to pure Ge, at wavelengths corresponding to the C-telecommunication band (1550 nm) and a 20-fold increase at wavelengths corresponding to the L-band (1620 nm). Measurements on a series of samples with different thicknesses reveal nearly identical dielectric functions, from which the composition reproducibility of the growth method is estimated to be as good as 0.1%. It is shown that a model that includes excitonic effects reproduces the measured onset of absorption using the direct band gap E₀ as essentially the only adjustable parameter of the fit.

Group-IV semiconductors, including alloys incorporating Sn, have been grown on dimensionally dissimilar Si substrates using novel molecular hydride chemistries with tunable reactivities that enable low temperature, CMOS compatible integration via engineering of the interface microstructure. Here we focus on properties of three such Ge-based systems including: (1) device quality Ge layers with thicknesses >5 μm possessing dislocation densities <105/cm2 are formed using molecular mixtures of Ge2H6 and highly reactive (GeH3)2CH2 organometallic additives circumventing the classical Stranski-Krastanov growth mechanism, (2) metastable GeSn alloys are grown on Si via reactions of Ge2H6 and SnD4, and (3) ternary SiGeSn analogs are produced lattice-matched to Ge-buffered Si using admixtures of SiGeH6, SiGe2H8, SnD4, Ge2H6, and Si3H8. Optical experiments and prototype device fabrication demonstrate that the ternary SiGeSn system represents the first group-IV alloy with a tunable electronic structure at fixed lattice constant, effectively decoupling band gap and strain and eliminating the most important limitation in device designs based on group-IV materials. Doping at levels higher than 10¹⁹ cm⁻³ (both p and n-type) is achieved for all the above semiconductor systems using a similar precursor chemistry approach. Electrical and infrared optical experiments demonstrate that doped GeSn and SiGeSn have mobilities that compare or exceed that of bulk Ge.

Ternary GeSiSn alloys have been demonstrated on Ge- and GeSn-buffered Si substrates. These alloys, with a two-dimensional compositional space, make it possible to decouple lattice constant and electronic structure for the first time in a group-IV system. A Kouvetakis and Menendez paper, in Thin Solid Films, reviews the basic properties of the GeSiSn alloy, presents some new results on its optical properties, and discusses the approach that has been followed to model heterostructures containing GeSiSn layers for applications in modulators, quantum cascade lasers, and photovoltaics.

As used herein a rare earth, [RE1, RE2, . . . REₙ], is chosen from the lanthanide series of rare earths from the periodic table of elements {⁵⁷La, ⁵⁸Ce, ⁵⁹Pr, ⁶⁰Nd, ⁶¹Pm, ⁶²Sm, ⁶³Eu, ⁶⁴Gd, ⁶⁵Tb, ⁶⁶Dy, ⁶⁷Ho, ⁶⁸Er, ⁶⁹Tm, ⁷⁰Yb and ⁷¹Lu} plus yttrium, ³⁹Y, and scandium, ²¹Sc, are included as well for the invention disclosed. “REO” is used generically to refer to rare earth oxide, rare earth nitride, rare earth phosphide and mixtures thereof compounds; “RE” may refer to one or more than one rare earth in combination.

### SUMMARY OF THE INVENTION

In some embodiments a photovoltaic structure, optionally a solar cell comprising one or more active junction layers, comprises a plurality of layers wherein an active junction layer is optionally Group IV based, optionally Group III-V based and/or optionally Group II-VI based. Frequently various active junctions are designed to operate in tandem such that a wide range of incident radiation, optionally solar radiation, is absorbed. Separating the one or more active junction layers from a substrate are transition layers designed to transition between a substrate of first composition and first lattice constant to a first active junction layer of second composition and second lattice constant. The transition layers comprise, optionally, a rare earth based layer(s) and, optionally, a Group IV based layer(s). Rare earth based layers comprise at least one rare earth in combination with at least one of oxygen, nitrogen and phosphorous. Group IV based layers comprise at least one of germanium and silicon; optionally, Group IV based layers comprise at least one of other Group IV materials such as carbon, tin and/or lead. In this manner a multi-junction solar cell is constructed on a substrate with one or more rare earth based layers and optionally one or more Group IV based layers between a multi-junction solar cell and a substrate. As used herein a multi-junction solar cell comprises one or more active junction layers comprising either Group IV, group III-V and/or Group II-VI based layers. In one embodiment a rare earth based layer and a Group IV based layer separate an active junction layer from a substrate.

Rare earth base layers are of a composition defined by [RE1]ₓ[RE2]_{y}[RE3]_{z}[J1]ᵤ[J2]ᵥ[J3]_{w} wherein 0<x, u≦5 and 0≦v, w, y, z≦5 and J is one of oxygen, nitrogen or phosphorus. Group IV based layers are of a composition defined by SiᵤGeᵥC_{w}SnₓPb_{y} wherein at least one of u or v is greater than zero and 0≦w, x, y, (v or u)≦5. Rare earth base layers and Group IV based layers may be single crystal, polycrystalline, microcrystalline, nano crystals, quantum dots or amorphous. In some embodiments rare earth based layers and Group IV based layers form an interleaved structure as in FIG. 9; in some embodiments there is no interleaving; in some embodiments only rare earth layers are present between Group IV semiconductors; in some embodiments only Group IV based layers are present. Deposition techniques for the various layers, including RE, Group IV, III-V, and Group II-VI compounds include chemical vapor deposition, PECVD, LPCVD, MOCVD, MBE, PVD, atomic layer deposition, liquid phase epitaxy, solid phase epitaxy, side-wall epitaxy, low-temperature CVD and others known to one knowledgeable in the art.

The present invention relates to semiconductor devices suitable for electronic, optoelectronic and energy conversion applications. In a particular form, the present invention relates to the fabrication of an energy conversion device through the combination of crystalline or amorphous semiconductors, insulators, rare-earth based compounds and substrates.

Triple junction materials are generally chosen from Group III-V materials, such as In, Ga, Al, As, P with the exact combinations tailored to specific energies but with restriction imposed by the choice of a germanium substrate or Ge support layer. By removing the restrictions of a germanium substrate, or support layer, new combinations of III-V alloys, and II-VI materials, are enabled. A lattice matched and/or engineered strained substrate or support layer with better current match and better band gap match to a broad selection of triple junction cell materials enables a higher efficiency multi-junction solar cell.

The instant invention discloses the use a substrate, optionally silicon, modified by the addition of various rare earth based layers and, optionally, Group IV based layers producing a multilayer, virtual substrate whose upper surface is lattice matched or, optionally, lattice-in-strain matched to a desired multi-junction solar cell or other photovoltaic device comprising material combinations from Groups III-V and/or II-VI and/or Group IV.

### BRIEF DESCRIPTION OF THE FIGURES

FIG. 1 shows a III-V tandem multi-junction cell over a lattice matched Ge layer and REO based layer; optionally IV or II-VI.

FIG. 2 shows lattice constants of various rare earths and Group IV materials.

FIG. 3 shows a III-V tandem multi-junction cell over a lattice matched GeSn layer and graded REO based layer.

FIG. 4 shows a III-V or II-VI tandem multi-junction cell over a lattice matched GeSn layer and graded REO/REN/REP based layer.

FIGS. 5a and 5b multiple rare earths and how composition may vary with layer thickness.

FIG. 6 shows lattice constants for various III-V and II-VI solar cells versus band gap.

FIGS. 7a, b and c show various embodiments for substrate and rare earth based layer and Group IV based layer.

FIGS. 8a, b and c show different example of strain balanced and lattice matched structures.

FIG. 9 shows possible embodiments for substrate and rare earth based layers and Group IV based layers.

FIGS. 10a and b shows an exemplary embodiment with graded rare earth composition between two Group IV based layers.

### DETAILED DESCRIPTION OF THE INVENTION

The instant invention discloses a structure to transition from a substrate of first composition to a semiconductor material of second composition, optionally, operable as a solar cell. A transition structure as defined herein comprises at least first rare earth based layer of third composition at a first surface and of fourth composition at a second surface; positioned such that the first surface is in contact with the substrate and the second surface is in contact with the semiconductor material; optionally, a Group IV based layer is between the rare earth based layer second surface and the semiconductor material. In some embodiments there are a plurality of rare earth based layers interleaved with Group IV based layers between a substrate and a semiconductor material of second composition.

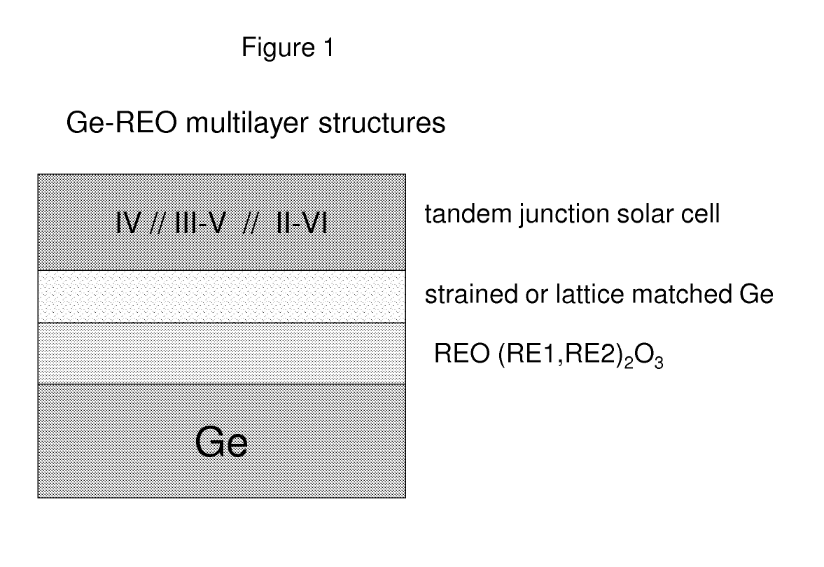

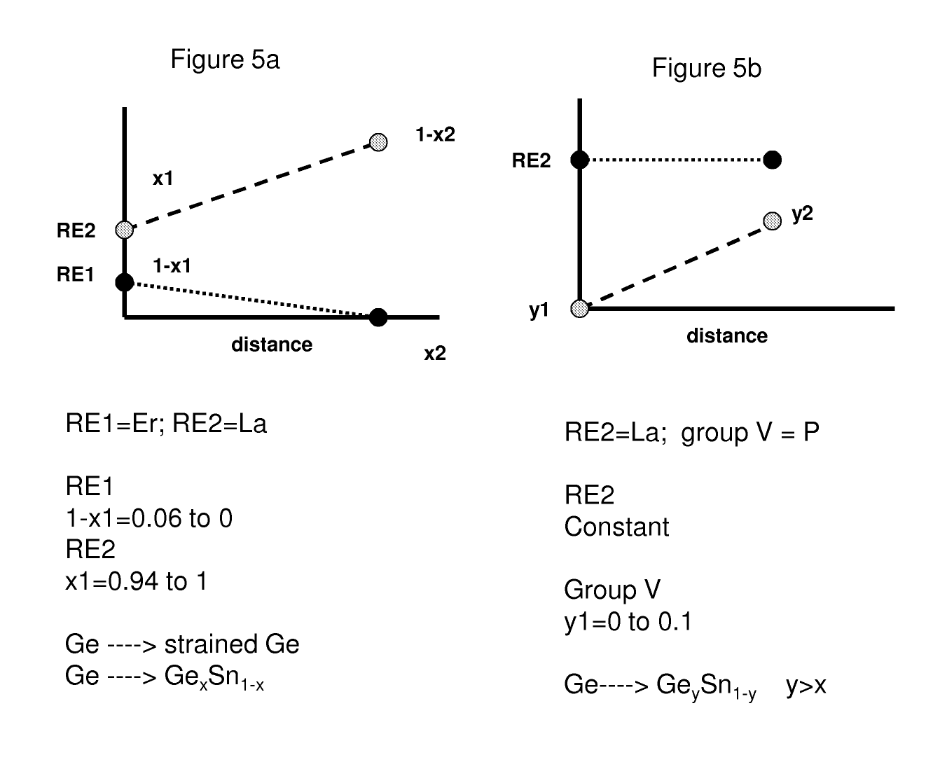

FIG. 1 shows one embodiment of, optionally, a III-V multi-junction tandem solar cell over a lattice matched Group IV based layer, in this case a predominately Ge layer and a REO based layer of mostly La₂O₃ and Er₂O₃ oxides. The Ge layer may comprise other Group IV elements such that the layer provides a surface approximately matched to a III-V multi-junction, tandem solar cell. In some embodiments the REO based layer of mostly La₂O₃ and Er₂O₃ oxides has a graded composition by varying the ratio of La₂O₃ to Er₂O₃ as noted in FIGS. 5a and b.

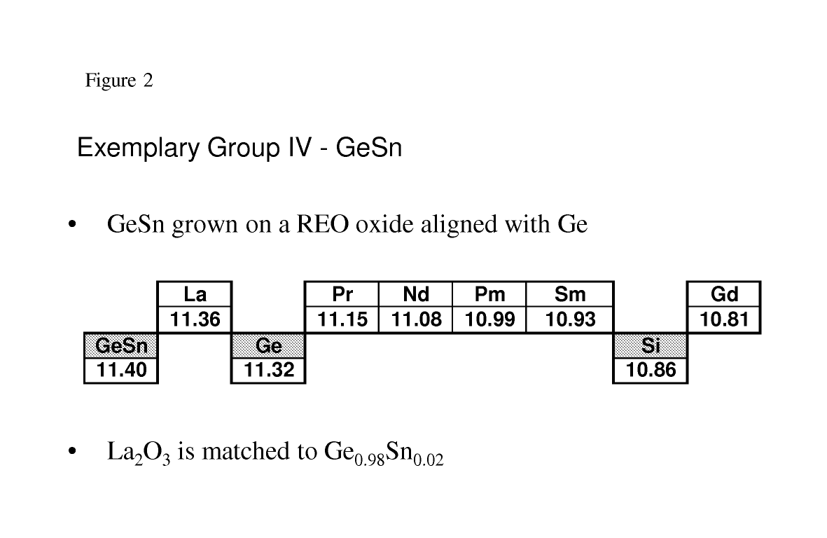

FIG. 2 shows lattice constants of various rare earths and Group IV materials and how various Group IV alloys may be combined to match lattice constants of various RE oxides; similar matching for rare earth nitrides and phosphides is also disclosed. Noted is the lattice match between La₂O₃ and Ge_{0.98}Sn_{0.02}. The lattice constants shown for the “RE” are for the rare earth oxide RE₂O₃; lattice constants shown for GeSn, Ge and Si are twice the actual lattice constant. Addition of Sn to Ge increases the lattice constant, making it more closely matched to a III-V compound such as InGaAs.

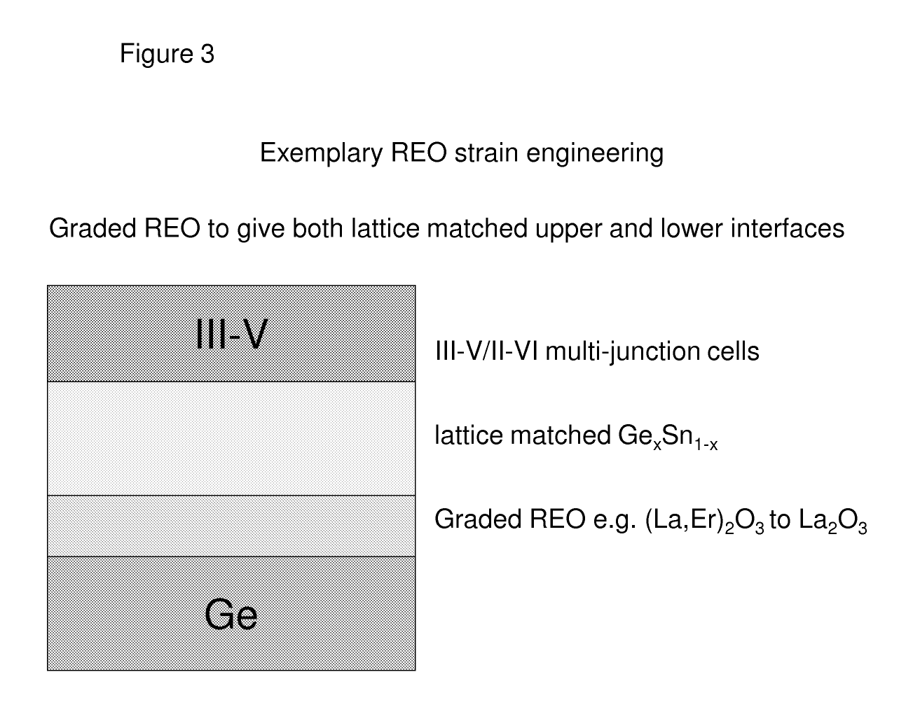

FIG. 3 shows one embodiment wherein a III-V multi-junction tandem cell is deposited over a lattice matched GeₓSn₁₋ₓ layer and REO based layer of La₂O₃ plus Er₂O₃ is graded to La₂O₃ to transition from a germanium substrate to a GeₓSn₁₋ₓ layer matched to a III-V layer.

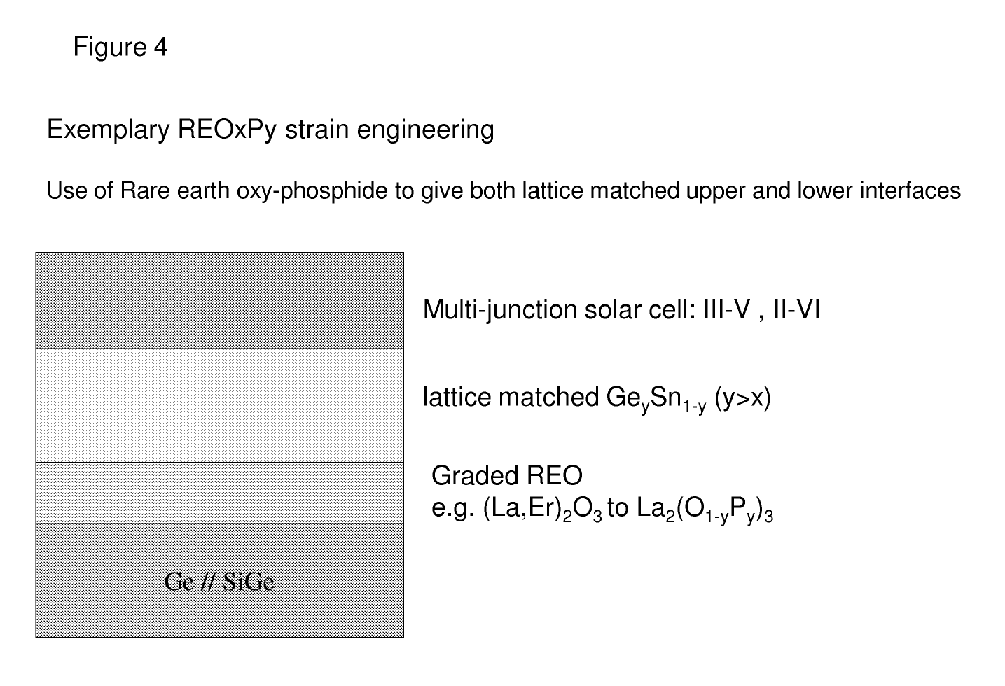

FIG. 4 shows III-V or II-VI tandem multi-junction cell over a lattice matched GeSn layer and graded REO/REN/REP based layer; shown is exemplary embodiment wherein La₂O₃ plus Er₂O₃ is graded to La₂(O_{1-y}P_{y})₃ to transition from a germanium substrate to a Ge_{y}Sn_{1-y} layer matched to a III-V or II-VI layer. Optionally the germanium substrate may be silicon or a SiGe layer or other suitable material; optionally the La₂(O_{1-y}P_{y})₃ ending composition may be another composition comprising one or more rare earths and one or more of oxygen, nitrogen and phosphorus and similarly with the beginning rare earth composition.

FIGS. 5a and 5b show exemplary embodiments of how multiple rare earth compositions may vary with layer thickness; other variations are also disclosed in the references. A binary rare earth compound may vary in RE1 and RE2 content; optionally, oxygen, nitrogen and phosphorus content may vary; Group IV specie, C, Si, Ge, Sn, Pb content may vary. The intent being to achieve a lattice constant/inherent lattice strain combination optimum for a specific solar cell composition based upon a starting substrate composition.

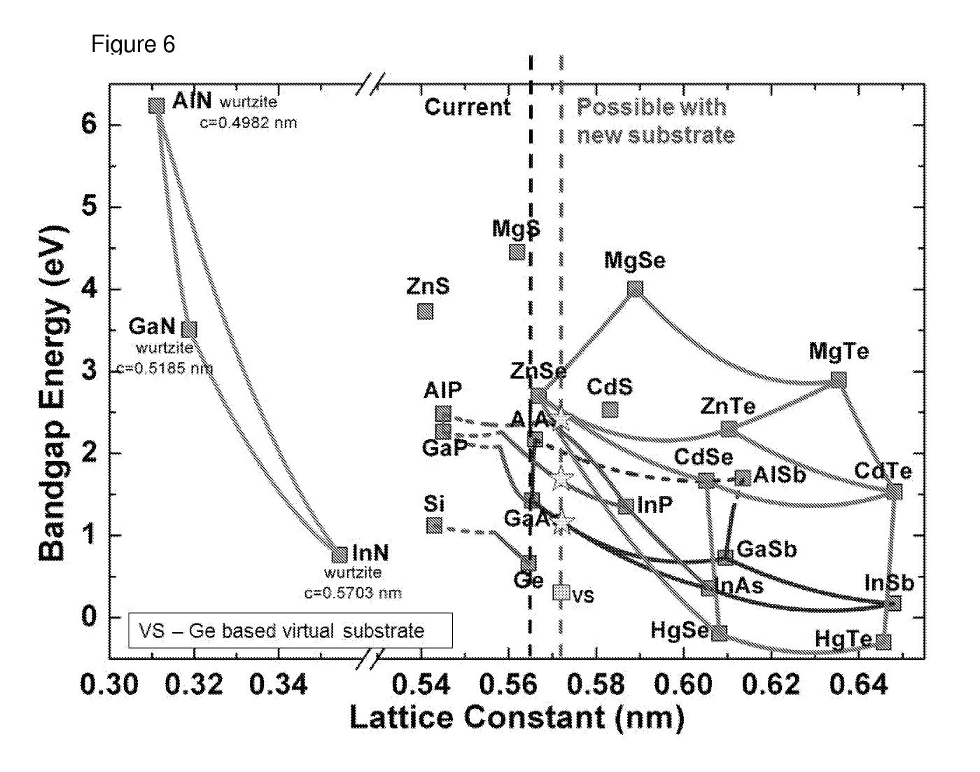

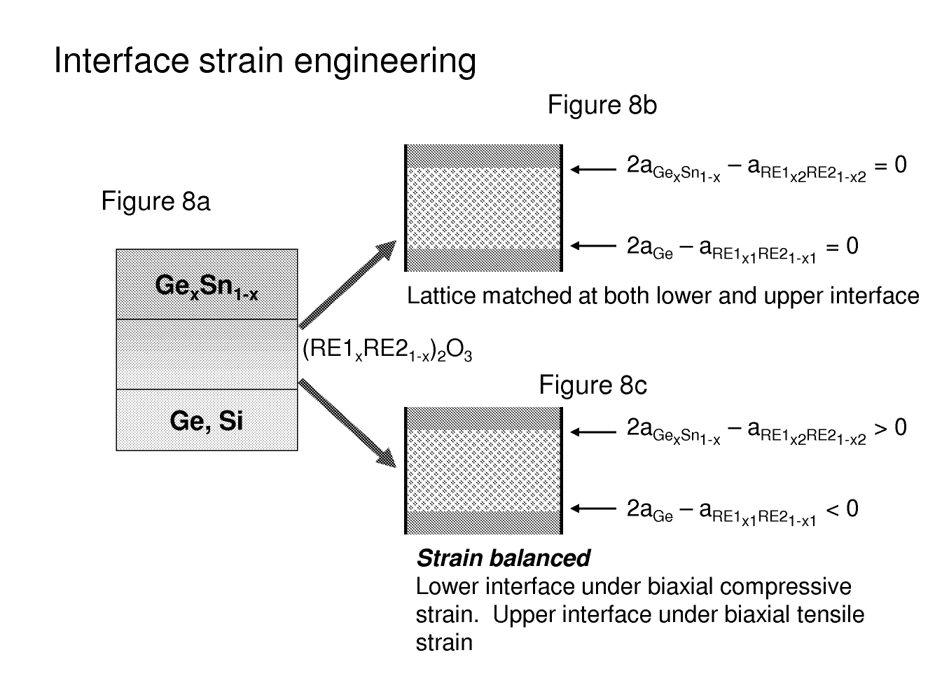

FIG. 6 shows lattice constants for various III-V and II-VI solar cells versus band gap. By choosing various combinations of rare earth oxides, nitrides and phosphides multiple lattice constant matching layers are achievable; in some embodiments a close lattice match is desirable; in some embodiments a match that results in compressive or tensile strain is desirable, as shown in FIGS. 8a, b and c.

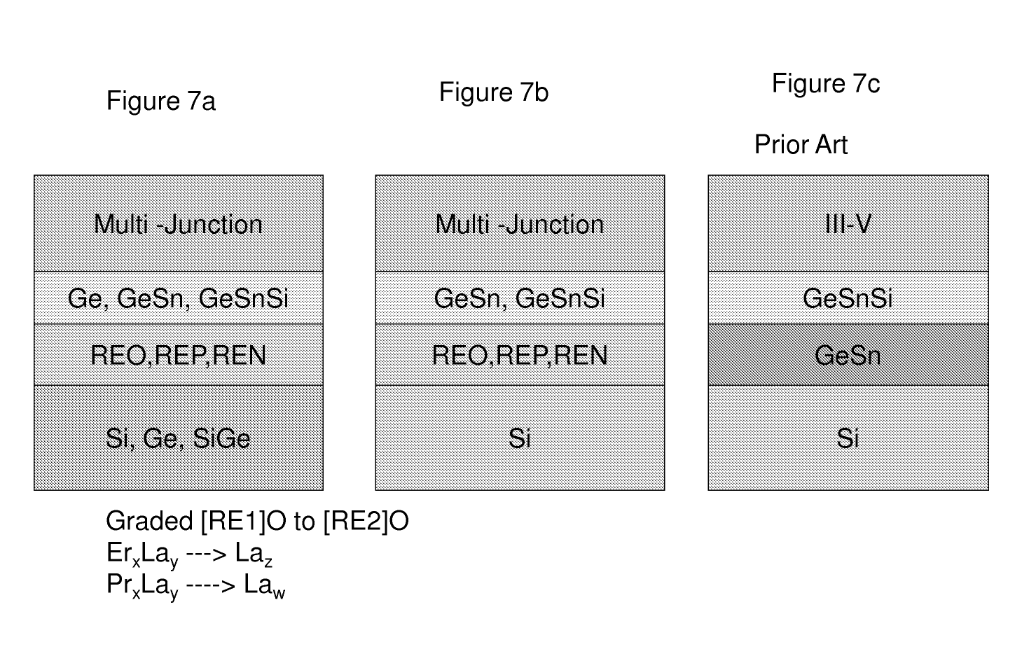

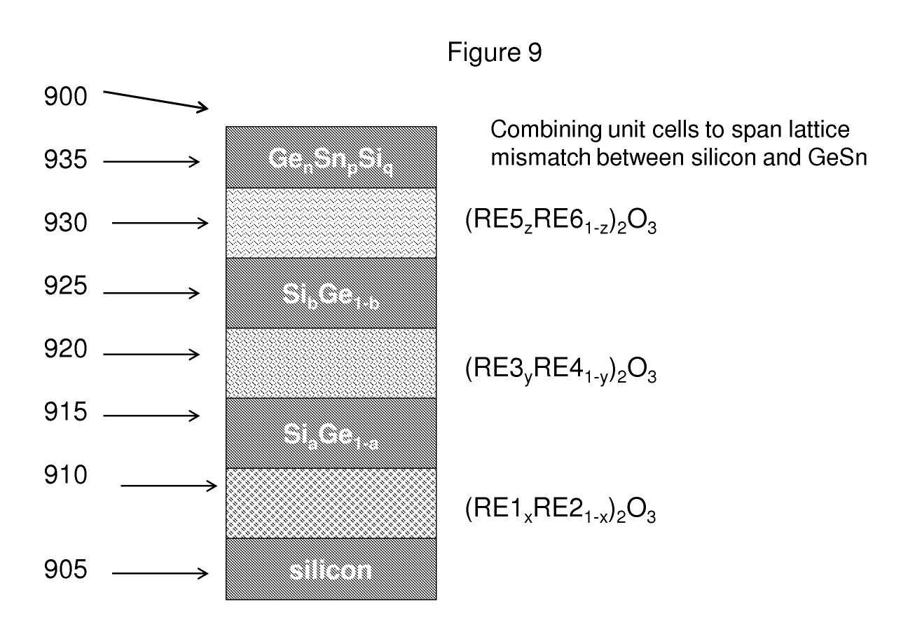

FIGS. 7a and b show various embodiments for Group IV based substrates, rare earth based layers and Group IV based layers. In some embodiments only one rare earth based layer in combination with one Group IV based layer is required to transition between a substrate or support layer and a multi-junction structure; in some embodiments multiple layers are required as shown in FIG. 9. Group IV based layers shown in FIGS. 7a, and b and c are exemplary embodiments; not shown embodiments may have combinations comprising silicon/germanium or Si—Ge—C or other Group IV combinations. FIG. 7c shows an embodiment disclosed in the prior art.

FIGS. 8a, b and c show examples of strain balanced and lattice matched structures. Note that the GeₓSn₁₋ₓ layer shown is exemplary and may be of different composition or not needed depending on the composition of a solar cell structure to be added to the structure shown. FIG. 8a shows an exemplary structure starting with a Group IV substrate, optionally, Si, Ge or SiGe combination; a RE1/RE2 based layer transitioning from one lattice constant to another; a top layer of GeSn alloy. FIG. 8b shows a lattice matched embodiment where the difference in lattice constant is about zero. In FIG. 8c a strain balanced embodiment is shown where one interface may be in compression and one in tensile strain.

FIG. 9 shows possible embodiments for a substrate and rare earth based layers and Group IV based layers. Structure 900 is exemplary of a transition structure between a silicon substrate or support layer 905 and a first solar cell structure positioned above layer 935, not shown. Layers 910, 920, and 930 are exemplary rare earth based layers; layers 915, 925, and 935 are group IV based layers; compositions shown are exemplary. Rare earth based layers may have a composition which varies along the growth direction or not; Group IV based layers may have a composition which varies along the growth direction or not; “O₃” is an exemplary composition and may be, optionally, nitrogen or phosphorous or combinations of all three.

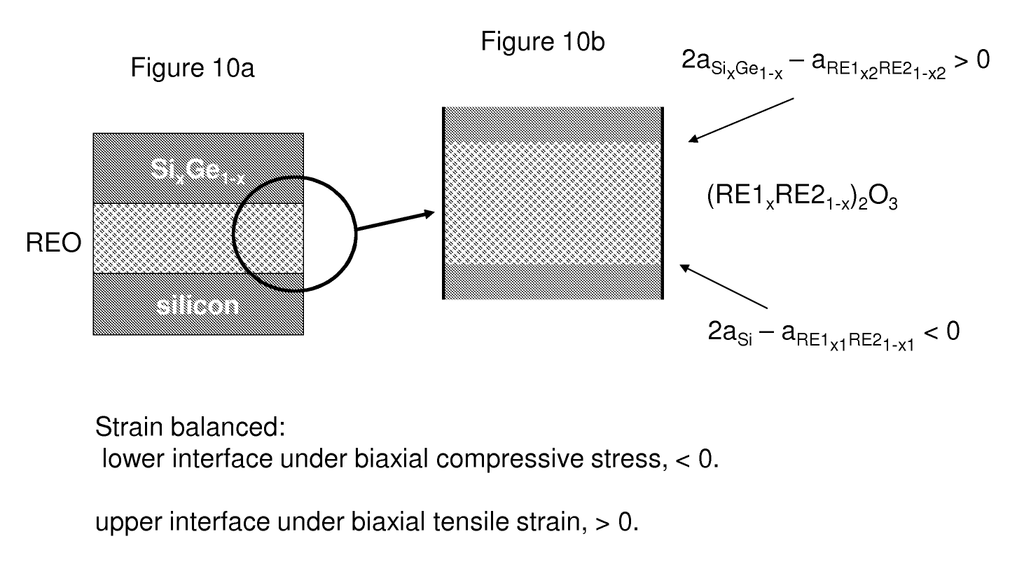

FIGS. 10a and b show an exemplary embodiment with graded rare earth composition between two Group IV based layers producing a layer with compressive strain on one surface and tensile strain on the other. The embodiments of FIGS. 10a and b are similar to FIG. 8c and are illustrating the range of composition combinations possible.

In some embodiments a structure within a solid state device comprises a first region of first composition, a second region of second composition and a third region of third composition separated from the first region by the second region; wherein the second region comprises a first and second rare-earth compound such that the lattice spacing of the first compound is different from the lattice spacing of the second compound and the third composition is different from the first composition; optionally, a solid state device comprises a first and third region comprising substantially elements only from Group IV; optionally, a solid state device further comprises a fourth region comprising substantially elements only from Groups III and V; optionally, a solid state device further comprises a fourth region comprising substantially elements only from Groups II and VI; optionally, a solid state device comprises a second region described by [RE1]ᵤ[RE2]ᵥ[RE3]_{w}[J1]ₓ[J2]_{y}[J2]_{z} wherein [RE] is chosen from a rare earth; [J1], [J2] and [J3] are chosen from a group consisting of Oxygen (O), Nitrogen (N), and Phosphorus (P), and 0≦v, w, y, z≦5, and 0<u, x≦5; optionally, a solid state device comprises a second region comprising a first portion of fourth composition adjacent said first region; a second portion of fifth composition; and a third portion of sixth composition separated from the first portion by the second portion and adjacent said third region wherein the fifth composition is different from the fourth and sixth compositions; optionally, a solid state device comprises a second portion comprising a first surface adjacent said first portion and a second surface adjacent said third portion and said fifth composition varies from the first surface to the second surface; optionally a solid state device comprises a second portion comprising a first surface adjacent said first portion and a second surface adjacent said third portion and comprises a superlattice with a structure comprising two layers of different composition which repeat at least once; optionally a solid state device comprises a first portion in a first state of stress and a third portion in a second state of stress different from the first state of stress.

In some embodiments a solid state device comprises first and second semiconductor layers separated by a rare earth layer wherein the first semiconductor layer is of composition X₍₁₋ₘ₎Yₘ; the second semiconductor layer is of composition XₙYₒZₚ and the rare earth layer is of a composition described by [RE1]ᵤ[RE2]ᵥ[RE3]_{w}[J1]ₓ[J2]_{y}[J2]_{z} wherein [RE] is chosen from a rare earth; [J1], [J2] and [J3] are chosen from a group consisting of Oxygen (O), Nitrogen (N), and Phosphorus (P), and 0≦v, w, y, z≦5, and 0<u, x≦5; and X, Y and Z are chosen from Group IV elements such that 0≦m≦1, 0≦o, p≦5, and n>0; optionally, a device comprises a rare earth layer comprising a first and second rare earth layer such that the composition of the first layer is different from the composition of the second layer and the lattice spacing of the first layer is different from the lattice spacing of the second layer.

In some embodiments a solid state device comprises a first semiconductor layer; a second semiconductor layer; and a rare earth layer comprising regions of different composition separating the first semiconductor layer from the second semiconductor layer; wherein the rare earth layer is of a composition described by [RE1]ᵤ[RE2]ᵥ[RE3]_{w}[J1]ₓ[J2]_{y}[J2]_{z} wherein [RE] is chosen from a rare earth; [J1], [J2] and [J3] are chosen from a group consisting of Oxygen (O), Nitrogen (N), and Phosphorus (P), and 0≦v, w, y, z≦5, and 0<u, x≦5 such that the composition of the rare earth layer adjacent the first semiconductor layer is different from the composition of the rare earth layer adjacent the second semiconductor layer; optionally, a device comprises first and second semiconductor materials chosen from one or more Group IV elements or alloys; optionally, a device comprises a rare earth layer comprising a first region adjacent said first semiconductor layer, a second region adjacent said second semiconductor layer and a third region separating the first region from the second region such that the composition of the third region is different from the first region and the second region.

In some embodiments a solid state device for converting incident radiation into electrical energy comprises a first semiconductor layer consisting of one or more Group IV elements; a second semiconductor layer consisting of one or more Group IV elements; a rare earth layer comprising regions of different composition separating the first semiconductor layer from the second semiconductor layer; wherein the rare earth layer is of a composition described by [RE1]ᵤ[RE2]ᵥ[RE3]_{q}[J1]ₓ[J2]_{y}[J2]_{z} wherein [RE] is chosen from a rare earth; [J1], [J2] and [J3] are chosen from a group consisting of Oxygen (O), Nitrogen (N), and Phosphorus (P), and 0≦v, w, y, z≦5, and 0<u, x≦5 such that the composition of the rare earth layer in contact with the first semiconductor layer is different from the composition of the rare earth layer in contact with the second semiconductor layer; and a third semiconductor layer comprising at least one active layer for converting incident radiation into electrical energy in contact with the second semiconductor layer; optionally, a solid state device wherein the rare earth layer composition in contact with the first semiconductor layer is such that the lattice constant of the first semiconductor layer is about the same as the lattice constant of the rare earth layer composition in contact with the first semiconductor layer; optionally, a solid state device wherein the rare earth layer composition in contact with the first semiconductor layer is such that there exists biaxial compressive strain between the rare earth layer and the first semiconductor layer; optionally, a solid state device wherein the rare earth layer composition in contact with the second semiconductor layer is such that the lattice constant of the second semiconductor layer is about the same as the lattice constant of the rare earth layer composition in contact with the second semiconductor layer; optionally, a solid state device wherein the rare earth layer composition in contact with the second semiconductor layer is such that there exists biaxial tensile strain between the rare earth layer and the second semiconductor layer; optionally, a solid state device wherein at least one of the Group IV elements of the second semiconductor layer composition is tin; optionally, a solid state device wherein the composition of the third semiconductor layer is chosen from either Group IV elements or Group III-V elements or Group II-VI elements such that incident radiation is converted into electrical energy.

It will be understood that when an element as a layer, region or substrate is referred to as being “on” or “over” or “adjacent” another element, it can be directly on the other element or intervening elements may also be present. In contrast, when an element is referred to as being “directly on” or “directly over” or “in contact with” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein a stratum, or, in the plural, strata, is a layer of material, optionally, one of a number of parallel layers one upon another.

It will also be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer, without departing from the scope of the present invention.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention. Embodiments described in the application may comprise one or more details, process techniques, parameters or other features of each embodiment mentioned as well as attributes knowledgeable to one in the art.

Foregoing described embodiments of the invention are provided as illustrations and descriptions. They are not intended to limit the invention to precise form described. In particular, it is contemplated that functional implementation of invention described herein may be implemented equivalently. Alternative construction techniques and processes are apparent to one knowledgeable with integrated circuit, light emitting device, solar cell, flexible circuit and MEMS technologies. Other variations and embodiments are possible in light of above teachings, and it is thus intended that the scope of invention not be limited by this Detailed Description, but rather by Claims following. All references to published material including patents and applications are included herein in their entirety by reference.

We claim:

1. A solid state device for converting incident radiation into electrical energy comprising:
a first region of first composition;
a second region of second composition; and
a third region of third composition separated from the first region by the second region; wherein the second region comprises a first rare-earth compound adjacent the first region and a second rare earth compound adjacent the third region such that the lattice spacing of the first compound is different from the lattice spacing of the second compound and the third composition is different from the first composition.

2. A solid state device of claim 1 wherein the first region comprises substantially elements only from Group IV.

3. A solid state device of claim 2 wherein the third region comprises substantially elements only from Groups III and V.

4. A solid state device of claim 2 wherein the third region comprises substantially only elements from Groups II and VI.

5. A solid state device of claim 1 wherein the second region consists of compounds described by [RE1]ᵤ[RE2]ᵥ[RE3]_{w}[J1]ₓ[J2]_{y}[J2]_{z} wherein [RE] is chosen from a rare earth; [J1], [J2] and [J3] are chosen from a group consisting of Oxygen (O), Nitrogen (N), and Phosphorus (P), and 0≦w, z≦5, and 0<u, v, x, y≦5 and RE1 is different from RE2 and J1 is different from J2.

6. A solid state device of claim 5 wherein the second region comprises:
a first portion of fourth composition adjacent the first region;
a second portion of fifth composition; and
a third portion of sixth composition separated from the first portion by the second portion and adjacent said third region wherein the fifth composition is different from the fourth and sixth compositions.

7. A solid state device of claim 6 wherein the second portion comprises a first surface adjacent said first portion and a second surface adjacent said third portion and said fifth composition varies from the first portion to the third portion.

8. A solid state device of claim 6 wherein the first portion is in a first state of stress and the third portion is in a second state of stress different from the first state of stress.

9. A solid state device for converting incident radiation into electrical energy comprising:
first and second semiconductor layers separated by a rare earth layer wherein the first semiconductor layer is of composition XₙYₒZₚ; the second semiconductor layer is of composition TₐU_{b}V_{c}W_{d} and the rare earth layer is of a composition described by [RE1]ᵤ[RE2]ᵥ[RE3]_{w}[J1]ₓ[J2]_{y}[J2]_{z} wherein [RE] is chosen from a rare earth; [J1], [J2] and [J3] are chosen from a group consisting of Oxygen (O), Nitrogen (N), and Phosphorus (P), and 0≦v, w, y, z≦5, and 0<u, x≦5; and X, Y and Z are chosen from Group IV elements such that 0≦o, p≦5, and n>0; and U, V, W are chosen from Group III-V elements such that 0≦c, d≦5, and a, b>0.

10. A solid state device of claim 9 wherein the rare earth layer comprises a first, second and third rare earth layer such that the composition of the first layer is different from the composition of the second layer and the lattice spacing of the first layer is different from the lattice spacing of the second layer and the first rare earth layer is adjacent the first semiconductor layer and the second rare earth layer is adjacent the second semiconductor layer and the third rare earth layer separates the first and second rare earth layers.

11. A solid state device for converting incident radiation into electrical energy comprising:
a first semiconductor layer;
a second semiconductor layer; and
a rare earth layer separating the first semiconductor layer from the second semiconductor layer; wherein the rare earth layer's composition changes from the first semiconductor layer to the second semiconductor layer such that the composition of the rare earth layer adjacent the first semiconductor layer is different from the composition of the rare earth layer adjacent the second semiconductor layer.

12. A solid state device of claim 11 wherein the first semiconductor layer is chosen from one or more Group IV elements or alloys.

13. A solid state device of claim 11 wherein the rare earth layer composition in contact with the first semiconductor layer is such that the lattice constant of the first semiconductor layer is substantially less than the lattice constant of the rare earth layer composition in contact with the first semiconductor layer.

14. A solid state device of claim 11 wherein the rare earth layer composition in contact with the first semiconductor layer is such that there exists biaxial compressive strain between the rare earth layer and the first semiconductor layer.

15. A solid state device of claim 11 wherein the rare earth layer composition in contact with the second semiconductor layer is such that the lattice constant of the second semiconductor layer is substantially less than the lattice constant of the rare earth layer composition in contact with the second semiconductor layer.

16. A solid state device of claim 11 wherein the rare earth layer composition in contact with the second semiconductor layer is such that there exists biaxial tensile strain between the rare earth layer and the second semiconductor layer.

17. A solid state device of claim 11 wherein at least one of the elements of the second semiconductor layer composition is tin.

18. A solid state device of claim 11 wherein the composition of the second semiconductor layer is chosen from a group consisting of Group IV elements, Group III-V elements and Group II-VI elements such that incident radiation is converted into electrical energy.
